(19) United States
(12) Patent Application Publication
(10) Pub. No.: US 2009/0279262 A1
(43) Pub. Date: Nov. 12, 2009

(54) HEAT DISSIPATING STRUCTURE

(76) Inventors: Meng-Cheng HUANG, Taipei (TW); Cheng-Tu Wang, Taipei (TW)

Correspondence Address: HDLS Patent & Trademark Services, P.O. BOX 220746, CHANTILLY, VA, 20153-0746, US

(21) Appl. No.: 12/118,839

(22) Filed: May 12, 2008

(51) Int. Cl. H05K 7/20

(52) U.S. Cl. 361/704

(57) ABSTRACT

A heat dissipating structure for a portable electronic device which includes a heat generating electronic member. The heat dissipating structure includes a base, a first heat pipe, a heat conducting sleeve, and a second heat pipe. The base is mounted on the heat generating electronic member. The base includes a through groove defined therein. One end of the first heat pipe is received in the through groove. The heat conducting sleeve includes a through hole defined therein. The through hole is configured for pivotably connecting the other end of the first heat pipe. One end of the coaxially joining with the first heating pipe in the heat conducting sleeve. The base is configured for conducting heat generated by the heat generating electronic member to the first heat pipe. It is advantageous that the heat dissipating structured can be mounted in limited space.

### BACKGROUND

1. Technical Field

The present invention generally relates to a heat dissipating structure, and more particularly, to a heat dissipating structure for a portable electronic device including a heat generating electronic member.

2. Discussion of Related Art

With continuous development of technology, operating rate of electronic members employed in various kinds of electronic devices are becoming higher and higher, as a same time, more and more heat is generated in electronic devices. In order t ensure operating of electronic devices, the temperature thereof must be maintained in a predetermined range; therefore, a heat dissipating devices is needed for dissipating heat generated by electronic devices.

FIG. 1 illustrates a heat dissipating structure generally employed in a laptop computer 10. The heat dissipating structure includes a base 11, a first heat pipe 12, a pivotal stand 13, and a second heat pipe 14. The base 11 is mounted on a top surface of a heat generating electronic member 15. The base 11 is configured for conducting heat generated by the electronic member 15. One end of the first heat pipe 12 is fixed to the base 11 and the other end of the first heat pipe 12 is inserted into a first hole 131 formed in the pivotal stand 13. One end of the second heat pipe 14 is inserted into a second hole 132 formed in the pivotal stand 13 and the other end of the second heat pipe 14 is disposed in a display panel 101 of the laptop computer 10. The first hole 131 and the second hole 132 are parallel with each other. The heat dissipating structure is disposed in the main body 102 of the laptop computer 10 except that the second heat pipe 14 is disposed outside the display panel 101 of the laptop computer 10.

However, currently, laptop computers are required to be more and more thinner and portable, accordingly, the space in the main body of laptop computers is becoming tighter and tighter. The pivotal stand of the heat dissipating structure as mentioned above is apparently too big. In addition, a heat dissipating efficiency of the heat dissipating structure doesn't increase as the cross area of the pivotal stand increases. Therefore, what is needed is a compact heat dissipating structure.

### BRIEF SUMMARY

The present invention is to provide a heat dissipating structure for a portable electronic device. The heat dissipating structure dissipates heat generated by a heat generating electronic member. Specifically, the heat generated is conducted by a base mounted on the heat generating electronic member to a first heat pipe. One end of the first heat pipe is pivotably disposed in a side of a through hole of a heat conducting sleeve, and a second heat pipe coaxially joins with the first heat pipe in the other side of the through hole. As a result, a highly compacted heat dissipating structure is obtained. It is advantageous that the heat dissipating structured can be mounted in limited space.

In one exemplary embodiment, a heat dissipating structure for a portable electronic device which includes a heat generating electronic member is provided. The heat dissipating structure includes a base, a first heat pipe, a heat conducting sleeve, and a second heat pipe. The base is mounted on the heat generating electronic member. The base includes a through groove defined therein. One end of the first heat pipe is received in the through groove. The heat conducting sleeve includes a through hole defined therein. The through hole is configured for pivotably connecting the other end of the first heat pipe. One end of the coaxially joining with the first heating pipe in the heat conducting sleeve. The base is configured for conducting heat generated by the heat generating electronic member to the first heat pipe.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic view of a generally used heat dissipating structure for a laptop computer;

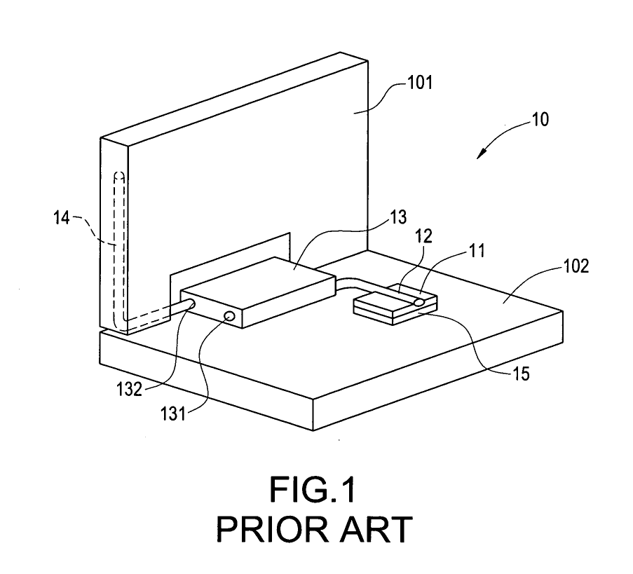

FIG. 2 is a perspective exploded view of a heat dissipating structure in accordance with an embodiment;

FIG. 3 is a perspective assembled view of the heat dissipating structure of FIG. 2;

FIG. 4 is a partial cross sectional view of the heat dissipating structure of FIG. 2;

FIG. 5 is a schematic view showing the heat dissipating structure of FIG. 2 is employed in a laptop computer;

FIG. 6 is a side cross sectional view of FIG. 5; and

FIG. 7 is another side cross sectional view of FIG. 5.

### DETAILED DESCRIPTION

The heat dissipating structure of the present invention will be describe in detail accompanying with the Figures; however, it is to be understood that the figures are intended to illustrate the present heat dissipating structure but not to limit the scope of the present invention.

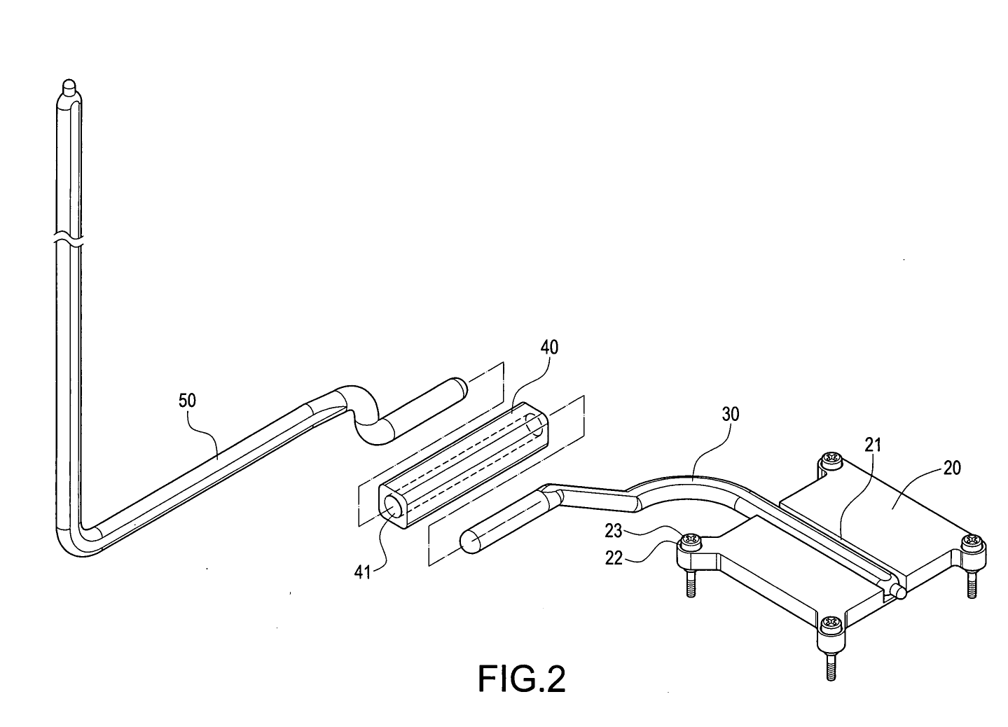

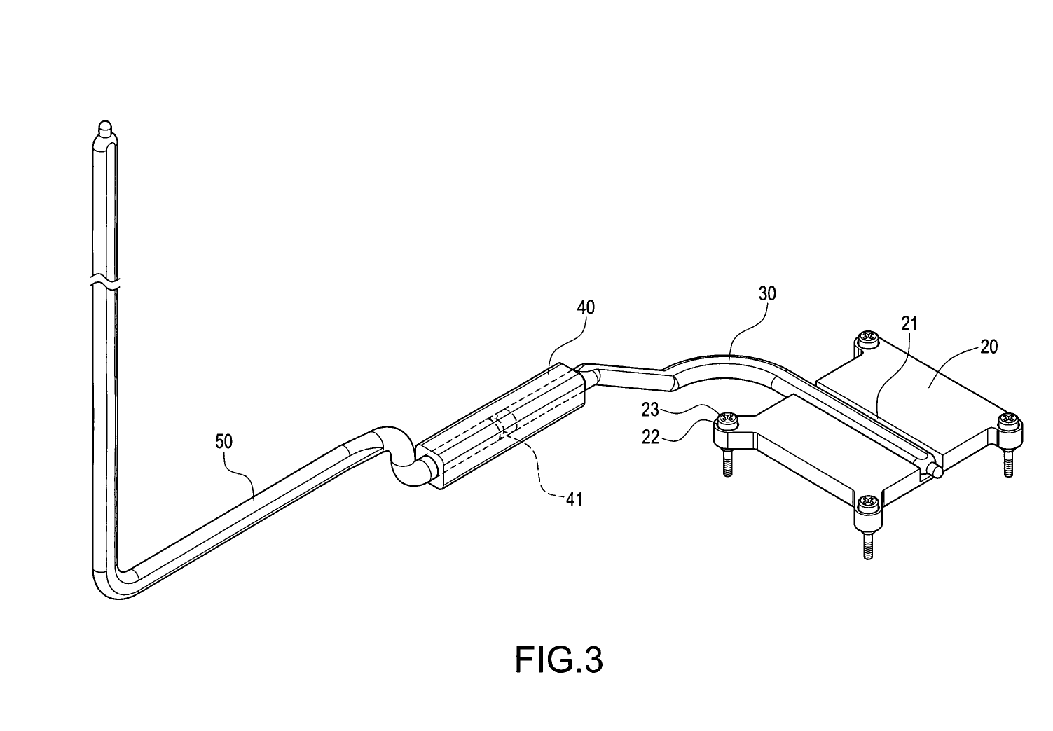

Referring to FIGS. 2 and 3, which respectively illustrate perspective exploded view and perspective assembled view of the present heat dissipating structure, a heat dissipating structure for dissipating heat for a portable electronic device is provided. The heat dissipating structure includes a base 20, a first heat pipe 30, a heat conducting sleeve 40 and a second heat pipe 50.

A through groove 21 is defined in the base 20. A group of mounting holes 22 is formed in each of two sides of the through groove 21. In the present embodiment, the mounting holes 2 are screw holes. The mounting holes 22 are configured for receiving a securing member 23 (e.g. bolts) so as to fix the securing member 23. The base 20 can be made of a material having good heat conductivity, for example, copper, silver and etc.

One end of the first heat pipe 30 is received in the though groove 21 of the base 20.

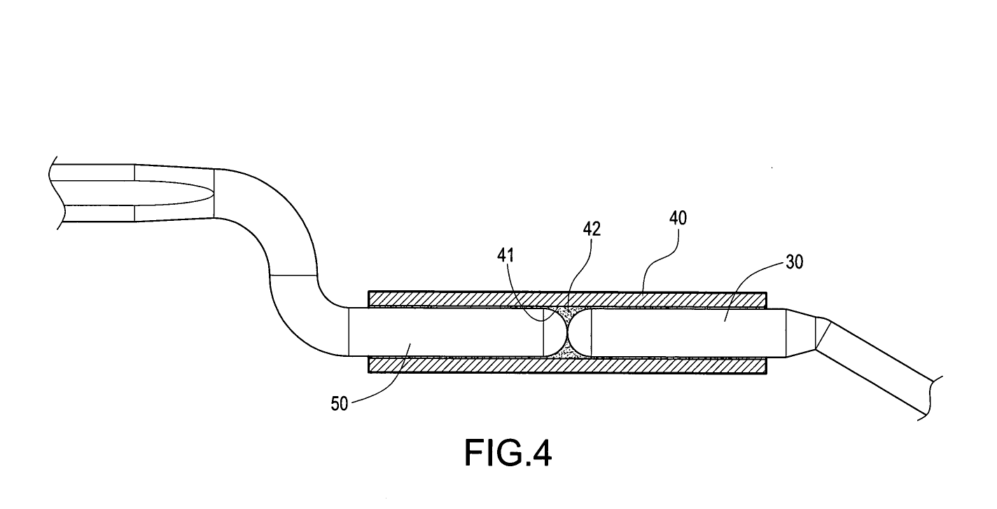

A through hole 41 is defined in the heat conducting sleeve 40. The through hole 41 is pivotably connecting the other end of the first heat pipe 30. As shown in FIG. 4, a heat conducting medium 42 (e.g. heat conducting paste) is distributed on an inner sidewall of the through hole 41 of the heating conducting sleeve 40. The heat conducting medium 42 is configured for increasing a heat conductivity of the heat conducting sleeve 40. That is, the heat can be efficiently transferred from the first heat pipe 30 to the heat conducting sleeve 40 via the heat conducting medium 42.

One end of the second heat pipe 50 coaxially joins with the first heat pipe 30 in the through hole 41 of the heat conducting sleeve 40. A diameter of the through hole 41 is slightly larger than a diameter of the first heat pipe 30 and the second heat pipe 50. As such, the first heat pipe 30 and the second heat pipe 50 can be easily inserted into the through hole 41 while a relative high bonding force can also be maintained between the heat conducting sleeve 40 and the two heat pipes.

As shown in FIG. 4, the heat dissipating structure is assembled with a laptop computer 60. The laptop computer 60 includes a display panel 601 and a main body 602. The heat dissipating structure includes a base 20, a first heat pipe 30, a heat conducting sleeve 40 and a second heat pipe 50. One end of the first heat pipe 30is received in the base 20, and the other end of the first heat pipe 30 is pivotably disposed in the heat conducting sleeve 40. One end of the second heat pipe 50 coaxially joins with the first heat pipe 30 in the heat conducting sleeve 40. The heat conducting sleeve 40 is disposed in a pivot 603 of the laptop computer 60. The base 20 is mounted on a surface of a heat generating member for dissipating heat generated by the heat generating member to the first heat pipe 30, and then the heat is transferred to the second heat pipe 50 via the heat conducting sleeve 40. The other end of the second heat pipe 50 is disposed in the display panel 601.

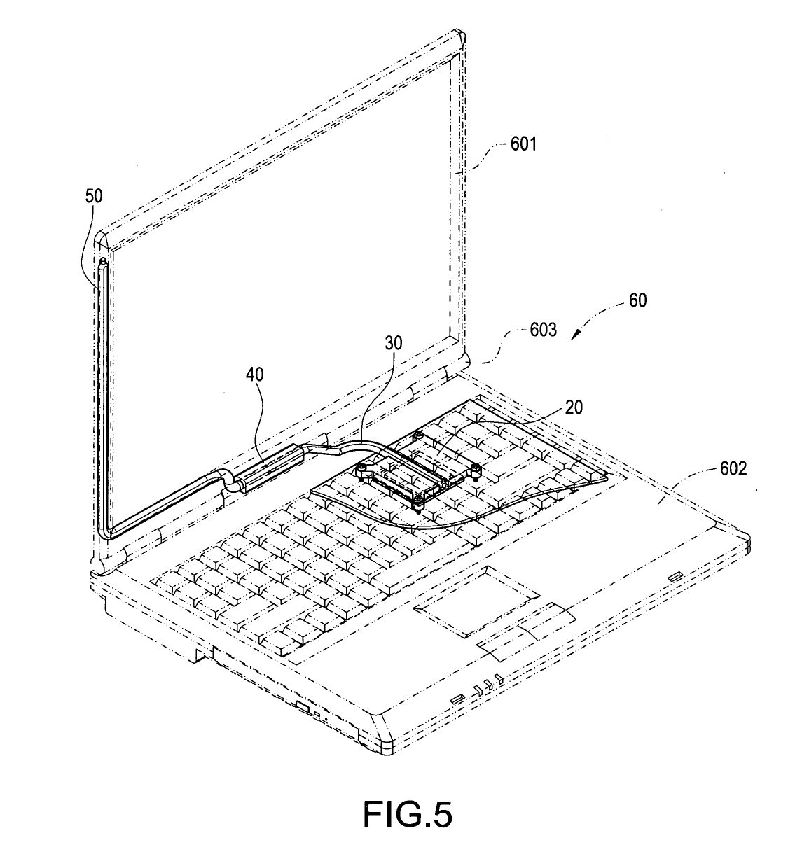

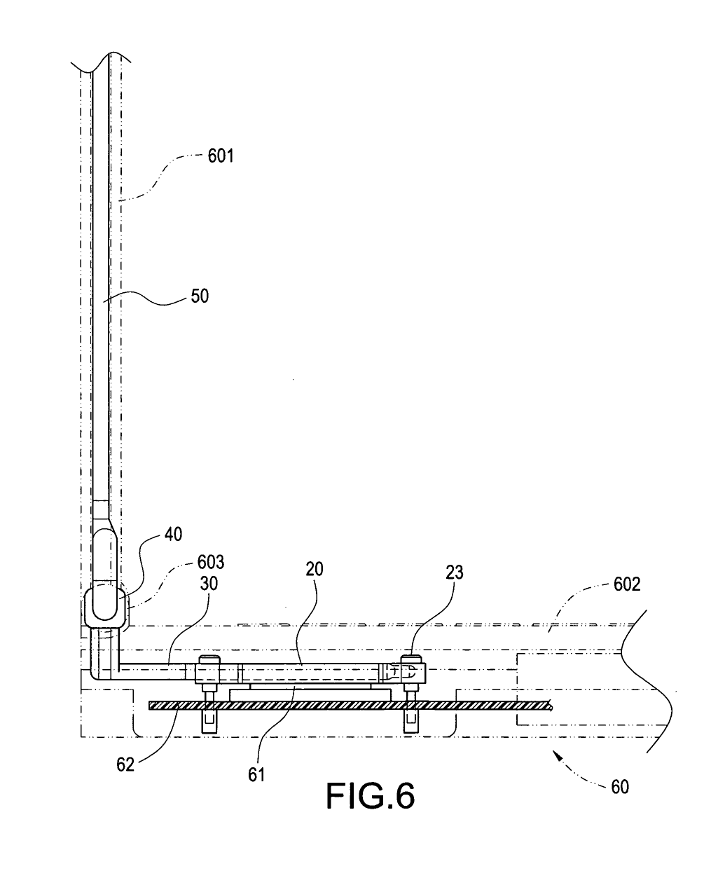

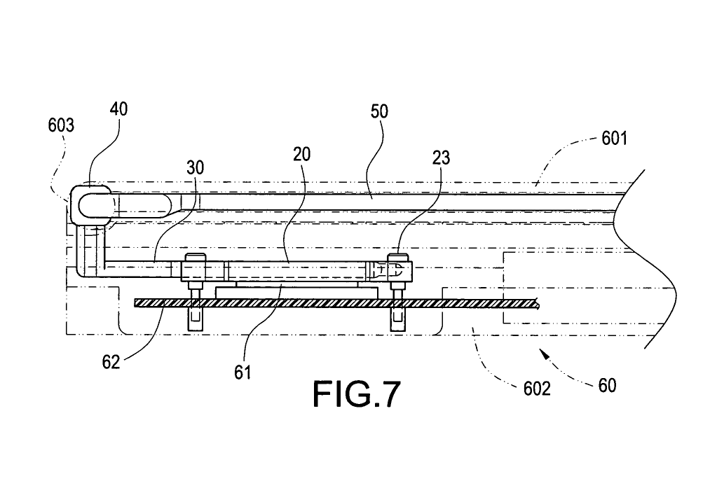

FIGS. 6 and 7 illustrate cross sectional view of FIG. 5, the base 20 is secured on a heat generating electronic member 61 (e.g. a CPU arranged on a printed circuit board 62 that is mounted in the main body 602) by a securing member 23. A dimension of the base 20 is structured and arranged to fit a dimension of the heat generating electronic member 61. As such, a surface of the base 20 is in fully contact with a surface of the heat generating electronic member 61 and a heat dissipating efficiency is maximized. In addition, the first heat pipe 30 and the second heat pipe 50 are coaxially connected to each other in the heat conducting sleeve 40. As a result, the heat conducting sleeve 40 can be received in the pivot 603 of the laptop computer 60; a space occupied by the heat dissipating structure is reduced.

In the present heat dissipating structure, the first heat pipe and the second heat pipe are coaxially connected in the heat conducting sleeve, thus, a volume of the heat conducting sleeve can be reduced, a space occupied by the heat dissipating structure can also be reduced. The heat dissipating structure can be employed in highly compacted portable electronic devices.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A heat dissipating structure for a portable electronic device comprising a heat generating electronic member, comprising:
a base mounted on the heat generating electronic member, the base comprising a through groove defined therein;
a first heat pipe with one end thereof received in the through groove;
a heat conducting sleeve comprising a through hole defined therein, the through hole pivotably connecting the other end of the first heat pipe; and
a second heat pipe with one end thereof coaxially joining with the first heating pipe in the heat conducting sleeve,
wherein a heat conducting medium is distributed on an inner sidewall of the through hole.

2. The heat dissipating structure as claimed in claim 1, wherein a group of mounting holes is formed in each of two sides of the through groove, the mounting holes are configured for receiving securing members.

3. The heat dissipating structure as claimed in claim 2, wherein the securing members are blots.

4. The heat dissipating structure as claimed in claim 1, wherein the heat conducting medium comprises heat conductive paste.

5. The heat dissipating structure as claimed in claim 1, wherein a diameter of the through hole is slightly larger than that of the first heat pipe and the second heat pipe.
